(19) United States
(12) Patent Application Publication
(10) Pub. No.: US 2020/0090884 A1
(43) Pub. Date: Mar. 19, 2020

(54) INFORMATION HANDLING SYSTEM KEYBOARD BACKLIGHT

(71) Applicant: Dell Products L.P., Round Rock, TX (US)

(72) Inventors: Erh-Chieh Chang, Taipei (TW); Wen-Pin Huang, Taipei (TW); Chih-Hao Chen, Taipei (TW); Chih-Ping Chang, Taipei (TW)

(73) Assignee: Dell Products L.P., Round Rock, TX (US)

(21) Appl. No.: 16/132,783

(22) Filed: Sep. 17, 2018

(51) Int. Cl. H01H 13/83; G06F 3/02; G06F 1/16; H03K 17/967

(52) U.S. Cl. CPC H01H 13/83; G06F 3/0202; H01H 2219/06; H03K 17/967; H01H 2219/036; G06F 1/1662

(57) ABSTRACT

An information handling system keyboard includes a backlight that illuminates keys by transmitting light from a light source through a light guide under the keys and reflects the light towards the keys with a reflector disposed under the light guide. Varied thickness of one or more of the light source, light guide and reflector at an intersection of the light source, light guide and reflector improve the efficiency of light transmission to the keys, thus providing for a thinner light guide and/or reduced illumination to have a given key illumination.

### BACKGROUND OF THE INVENTION

### Field of the Invention

The present invention relates in general to the field of information handling system input devices, and more particularly to an information handling system keyboard backlight.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems typically accept end user inputs through input devices, such as a keyboard. Desktop information handling systems generally interface with a peripheral keyboard through a cable, such as a USB cable, or a wireless interface, such as Bluetooth. Portable information handling systems typically support external peripheral keyboards; however, portable information handling systems also often include keyboards integrated in a portable housing. For example, portable information handling systems have rotationally coupled housing portions that rotate open to expose a keyboard and display in a clamshell configuration and rotate closed to protect the keyboard and display. Portable information handling systems typically integrate input/output (I/O) devices and processing components so that an end may operate the system in a portable mode free from external cables, such as power outlets. When operating in a portable mode, portable information handling systems generally power processing components with an integrated battery.

Generally, end users prefer portable information handling systems that have minimal weight and size for a desired performance. Portable information handling system width and length dimensions are generally driven by the size of the display integrated in the housing. Portable information handling system height and weight tends to depend more upon the capability of the system. For example, portable information handling systems that have more powerful processing components tend to have greater volume to address thermal management, such as by including active cooling mechanisms like a fan that generates a cooling airflow over heat-generating components. Portable information handling system manufacturers generally attempt to minimize housing height by selecting components that have less height and distributing the components across the width and length of the housing. Integrated keyboards tend to add to housing height since the keys travel vertically. A standard rubber dome keyboard key travels vertically 3.5 to 4 mm. Variations from standard key travel distances will reduce keyboard height with some impact on end user experience. Keyboard selection for a given portable information handling system platform generally depends upon housing height constraints.

Portable information handling systems are sometimes used in mobile conditions that have limited lighting. In reduced light conditions, end users may have difficulty seeing keyboard keys. To aid end user key inputs in reduced light conditions, portable information handling systems sometimes include a keyboard backlight that illuminates keys. A typical keyboard backlight has LED lights powered from a flexible printed circuit (FPC) that illuminates into a light guide panel (LGP) disposed over a reflector. Illumination distributed by the LGP reflects from the reflector through a masking to highlight the key values. One disadvantage to a keyboard backlight is that it tends to increase the height of the keyboard and, thus, the portable information handling system housing. For instance, in one example embodiment, including a keyboard backlight increases keyboard height by 0.25 mm. Another disadvantage of a keyboard backlight is that it increases power consumption, thus reducing battery life when operating in a portable mode. The amount of power consumed by a keyboard backlight depends upon the number of LEDs included in the backlight, the amount of illumination that each LED provides, and the thickness of the LGP that carries the light. For instance in one embodiment, a reduction in thickness of an LGP from 0.25 mm to 0.2 mm transmits 82.29% of the illuminated light.

### SUMMARY OF THE INVENTION

Therefore, a need has arisen for a system and method which efficiently illuminates a keyboard in limited vertical height.

In accordance with the present invention, a system and method are provided which substantially reduce the disadvantages and problems associated with previous methods and systems for illumination of a keyboard. Varied thickness of one or more of a light source, light guide and/or reflector in a keyboard backlight provides efficient transmission of light from the light source through the light guide for reflection at the keys.

More specifically, an information handling system processes information with processing components disposed in a housing, such as a central processing unit (CPU), random access memory (RAM) that execute instructions of an operating system and/or applications and presents output as visual images at a display. A keyboard having plural keys interfaces with the CPU to provide end user inputs based upon key presses, such as that strike against a membrane that detects touches by the keys. A keyboard backlight illuminates the keys, such as to enable end user visual identification of key values in low light conditions. The keyboard backlight includes one or more light sources that direct light into a light guide disposed over a reflector and under the keys so that the keys are illuminated from below. Variable thickness of one or more of the light source, light guide and/or reflector aid transmission of illumination from the light source to the keys. For example, a light guide has thickness that includes the thickness of the light source at the exit of illumination and narrows in thickness as the light guide extends distal the light source and towards the keys. In the example embodiment, the reflector has reduced thickness or even no thickness at the intersection of the light source and increases in thickness as the reflector extends distal the light source and towards the keys so that the total thickness of the keyboard backlight remains constant.

The present invention provides a number of important technical advantages. One example of an important technical advantage is that a keyboard backlight illuminates keyboard keys with improved efficiency and in a limited vertical height. Improved transmission of illumination from LEDs to a light guide panel allows reduced keyboard thickness through selection of a thinner light guide panel and inclusion of fewer LEDs for given amount of illumination provided to the keyboard keys. In one example embodiment, keyboard backlight thickness was reduced from 0.25 mm to 0.20 mm. In another example embodiment, more efficient light transmission reduced the number of LEDs of a keyboard backlight from 10 to 8, thus reducing system cost by $0.20 and reducing power consumption for a given brightness by 20 percent.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts an exploded view of a portable information handling system having a backlit keyboard;

FIG. 2 depicts a side cutaway view of a keyboard having a backlight integrated at a lower surface below the keys;

FIG. 3 depicts a side cut away view of a backlight having a varied thickness of a reflector and LED light source at their intersection with a light guide;

FIG. 4 depicts a side cut away view of a backlight having a varied thickness of a reflector and light guide at their intersection with a light source; and

FIG. 5 depicts a side cut away view of a backlight having a varied thickness of a reflector and light guide at their intersection with a light source and a liquid-optically clear adhesive integrated at the intersection.

### DETAILED DESCRIPTION

An information handling system keyboard backlight illuminates from a light source through a light guide above a reflector with a variable thickness intersection to improve light transmission efficiency. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

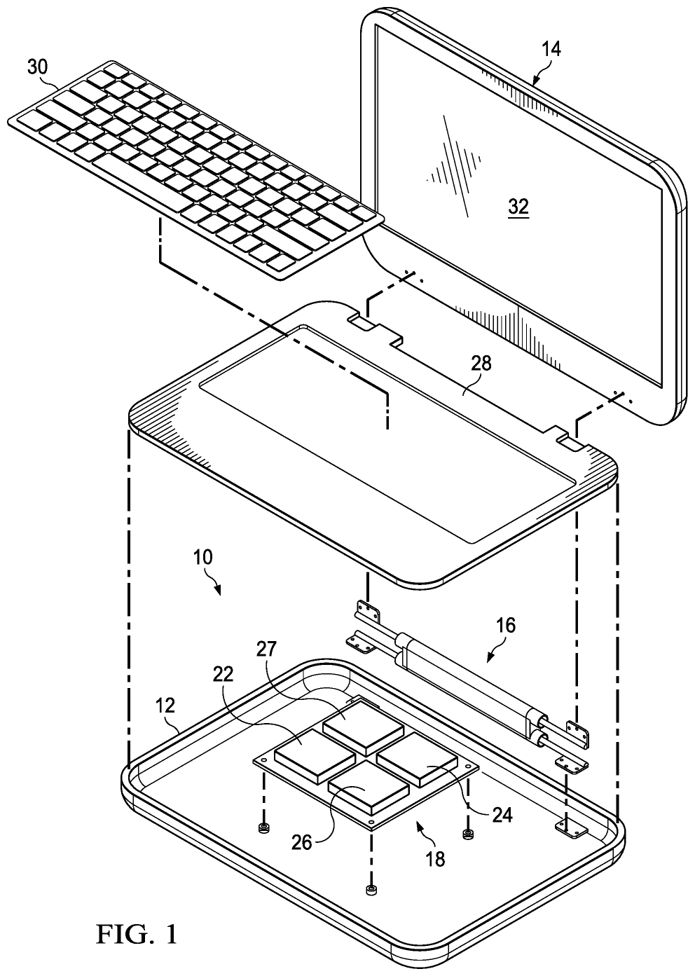

Referring now to FIG. 1, an exploded view depicts a portable information handling system 10 having a backlit keyboard 30. In the example embodiment, information handling system 10 has a portable configuration with a main housing portion 12 rotationally coupled to a lid portion 14 by a hinge 16. Main housing portion 12 contains a motherboard 18 that supports communications between processing components that cooperate to process information. In the example embodiment, the processing components include a central processing unit (CPU) 20 that executes instructions to process information and random access memory (RAM) 22 that stores the instructions and information. A chipset 24 manages the other processing components with various processing resources and instructions stored in flash memory. A solid state drive (SSD) 26 provides persistent storage of information, such as an operating system and applications that execute on CPU 20. As an example, preboot instructions executing on a processing resource of chipset 24, such as an embedded controller 27, retrieves the operating system from SSD 26 for execution on CPU 20. A main housing portion upper surface 28 couples over main housing portion 12 to protect the processing components an support a keyboard 30 that accepts end user keyed inputs, such as by communicating the keyed inputs through an embedded controller 27 to CPU 20. A graphics controller within chipset 24 provides visual information from CPU 20 to a display 32 integrated in lid housing portion 12 for presentation as visual images. In the example embodiment, display 32 is held in a viewing position over keyboard 30 so that an end user can make typed inputs while viewing display 32. The information handling system 10 depicted by FIG. 1 provides an example of an integrated keyboard that accepts keyed inputs in a mobile configuration; however alternative embodiments that use a backlight to illuminate keyboard keys may include peripheral keyboards separate from an information handling system.

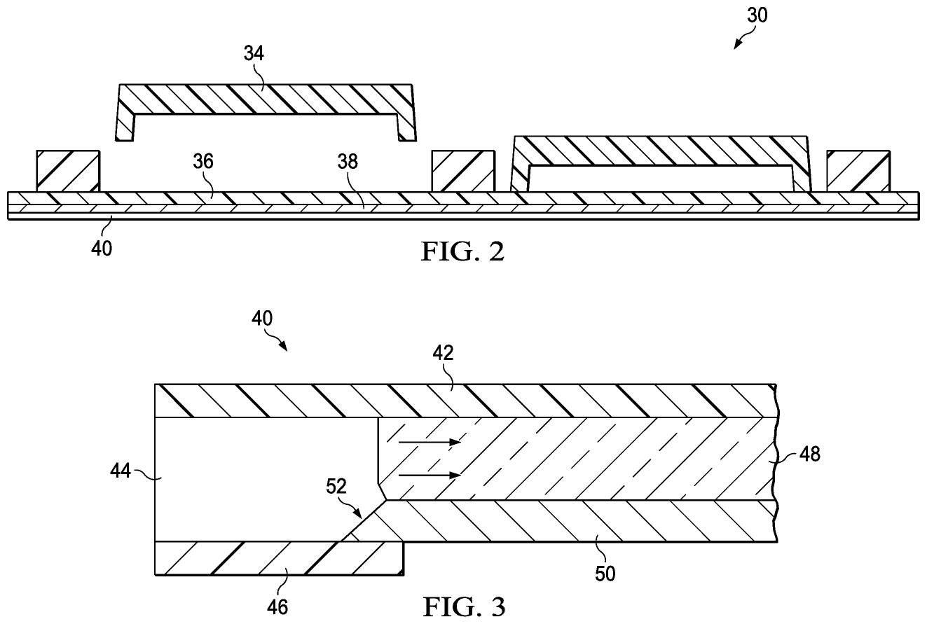

Referring now to FIG. 2, a side cutaway view depicts a keyboard 30 having a backlight 40 integrated at a lower surface below the keys 34. Keyboard 30 accepts inputs by depression of keys 34 downward against a membrane 36 that senses contact by key 34. A support plate 38 disposed under membrane 36 provides physical support against a press by key 34 to apply pressure at membrane 36 for key detection. Backlight 40 couples to the bottom surface of support plate 38 and provides illumination upwards towards keys 34 to illuminate the key values, such as through openings of support plate 38. In various embodiments, membrane 36, support plate 38 and backlight 40 may be vertically stacked in different orders with openings arranged to illuminate keys 34 from backlight 40. Backlight 40 adds some vertical height to the overall structure of keyboard 30 that increases the height of an information handling system integrating keyboard 30.

Referring now to FIG. 3, a side cut away view depicts a backlight 40 having a varied thickness of a reflector 50 and LED light source 44 at their intersection 52 with a light guide 48. In the example embodiment, backlight 40 has a total thickness of 0.30 mm with LED light source 44 generating illumination out a side surface and into light guide 48, which guides the illumination away from LED light source 44 and under keys 34 of keyboard 30. A flexible printed circuit 46 disposed on the bottom surface of backlight 40 provides power to LED light source 44. A masking 42 at the upper surface of backlight 40 directs light towards keys 34 for illumination. Reflector 50 is disposed below light guide 48 to reflect light upwards towards keys 34. In the example embodiment, light guide 48 and reflector 50 have a constant thickness from the LED light source 44 intersection 52 and distal away from LED light source 44. To improve light transmission from LED light source 44 into light guide 48, reflector 50 has an inclined extension that proceeds under light source 44, which has a matching incline to accept reflector 50. The variable thickness of light source 44 and reflector 50 provide increased illumination from light source 44 into light guide 48. That is, light leaving the bottom side surface of LED light source 44 is reflected by reflector 50 towards light guide 48. The example embodiment has a linear incline, however, alternative embodiments have a parabolic or other shaped variable thickness in reflector 50 to improve reflection into light guide 48. In the example embodiment, an LED light source has a modified base to accept the inclined surface of reflector 50, however, in alternative embodiments, other types of light sources may be used, such as an OLED material.

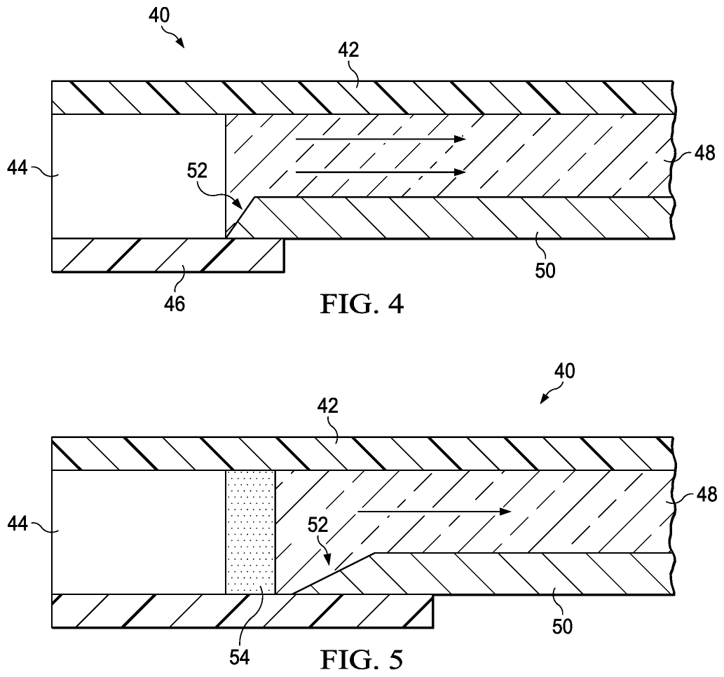

Referring now to FIG. 4, a side cut away view depicts a backlight 40 having a varied thickness of a reflector 50 and light guide 48 at their intersection 52 with a light source 44. In the example embodiment, LED light source has a vertical side surface that illuminates light towards light guide 48. To improve transmission of light from LED light source 44 into light guide 48, light guide 48 has an increased thickness proximate light source 44 so that light guide 48 has substantially the same height as light source 44. In order to provide the additional vertical space for increased light guide 48 thickness, reflector 50 has a decreased thickness at the intersection 52 with light source 44. In the example embodiment, reflector 50 starts at light source 44 with zero thickness and then gradually increases in thickness distal light source 44. The example embodiment depicts a linear change in thickness of light guide 48 and reflector 50 as the distance increases from light source 44 until thickness remains constant under keys 34. The length and gradient of the varied thickness may vary based upon manufacture constraints and light transmission efficiency. In an alternative embodiment, a nonlinear change in thickness may be used, such as a parabolic reflection surface that directs light into light guide 48. In another alternative embodiment, reflector 50 may have some thickness at the intersection 52 with light source 44 and, in one embodiment, reflector 50 may also extend under light source 44 as shown in FIG. 3 while having a reduced thickness at the intersection 52 of light source 44 and light guide 48 to increase light transmission to light guide 48. In various embodiments where light guide 48 has greater thickness proximate light source 44 than distal light source 44, the increased light guide thickness may match the thickness of light source 44, or may have greater or less thickness than light source 44.

Referring now to FIG. 5, a side cut away view depicts a backlight 40 having a varied thickness of a reflector 50 and light guide 48 at their intersection 52 with a light source 44 and a liquid-optically clear adhesive 54 integrated at the intersection 52. In the example embodiment, light source 44 and light guide 48 each have a thickness at their intersection 52 that extends between the upper and lower surfaces of backlight 40 so that light transmits efficiently into light guide 48. Light guide 48 tapers in thickness as it extends away from light source 44 and reflector 50 increases in thickness until a steady thickness of both is maintained. In some manufacture conditions, a gap can form between light guide 48 and light source 44 that impacts the efficiency of light transmission. To increase the efficiency of light transmission from light source 44 to light guide 48, a liquid optically clear adhesive 54 is inserted into the gap and cured, such as with UV light.

Although the present invention has been described in detail, it should be understood that various changes, substitutions and alterations can be made hereto without departing from the spirit and scope of the invention as defined by the appended claims.

1. A portable information handling system comprising:
a housing;
processing components disposed in the housing and operable to process information;
a display disposed in the housing and interfaced with the processing components, the display operable to present information as visual images;
a keyboard having plural keys, the keyboard disposed in the housing and interfaced with the processing components, the keyboard operable to accept inputs at the keys and communicate the inputs to the processing components; and
a backlight integrated with the keyboard, the backlight having at least one LED operable to generate illumination, a reflector disposed below one or more of the keys and aligned to reflect light towards the one or more keys, and a light guide disposed between the reflector and the one or more of the keys, the light guide operable to guide the illumination from the LED towards the one or more of the keys, the LED, light guide and reflector having a common thickness at the intersection of the LED, the light guide and the reflector, a liquid-optically clear adhesive coupling the LED and the light guide, the reflector having the common thickness from the LED through the liquid-optically clear adhesive and for a predetermined distance then a variable distance, the reflector after the predetermined distance ramping upwards to reduce a height of the light guide from the height of the LED at the intersection to a reduced height after the predetermined distance.

2. (canceled)

3. (canceled)

4. The portable information handling system of claim 1 wherein the light guide and reflector taper the variable height to a location distal the LED and then maintain a constant height as the distance from the LED increases.

5. The portable information handling system of claim 4 wherein the light guide and reflector taper in a linear manner.

6. The portable information handling system of claim 4 wherein the light guide and reflector taper in a parabolic manner.

7. (canceled)

8. (canceled)

9. (canceled)

10. A method for illuminating an information handling system keyboard, the method comprising:
generating illumination with a light source, the illumination directed out a side surface of the light source;
coupling the light source to a light guide with a liquid optically-clear adhesive;
accepting the illumination from the side surface through the liquid optically-clear adhesive and at the light guide that transmits the illumination from the light source to under one or more of the keyboard keys; and
reflecting light toward the one or more keys with a reflector disposed under the light guide;
wherein the combined thickness of the light guide and the reflector varies after a predetermined distance from an intersection of the light guide and the liquid optically-clear adhesive, the reflector closer to the keys under the one or more keys to define a reduced height of the light guide.

11. The method of claim 10 wherein the combined thickness varies proximate the location of the intersection to a location under one or more of the keys with the light guide having a greater height proximate the light source and a reduced height distal the light source.

12. The method of claim 11 wherein the reflector has no height proximate the light source and increased height distal the light source.

13. The method of claim 12 wherein the light source comprises an LED.

14. The method of claim 10 wherein the combined thickness varies proximate the location of the intersection to a location under one or more keys with the reflector having a reduced height under the light source and an increased height distal the light source and under the light guide.

15. (canceled)

16. (canceled)

17. A keyboard comprising:
a base plate;
a backlight disposed over the base plate;
a membrane disposed over the backlight; and
plural keys disposed over the membrane, the keys biased away from the membrane, the membrane detecting inputs by impact of keys depressed to touch the membrane;
wherein the backlight comprises:
one or more light sources;
a light guide proceeding from at least one of the light sources under one or more of the plural keys, the light guide coupled to the one or more light sources with a liquid optically clear adhesive disposed in a space between the light guide and the one or more light sources; and
a reflector disposed under the light guide to reflect light towards the one or more keys, the light guide and reflector having a varied thickness from the light source towards the one or more keys, the light guide having a height of the light source proximate the light source and for at least a predetermined distance away from the light source, the reflector after the predetermined distance defined a reduced thickness of the light guide.

18. (canceled)

19. (canceled)

20. (canceled)
